(19) United States
(12) Patent Application Publication
(10) Pub. No.: US 2021/0134617 A1
(43) Pub. Date: May 6, 2021

(54) SUBSTRATE TREATMENT APPARATUS

(71) Applicant: SEMES CO., LTD., Cheonan-si (KR)

(72) Inventors: Yong Jun SEO, Hwaseong-si (KR); Ye Rim YEON, Hwaseong-si (KR); Pil Kyun HEO, Hwaseong-si (KR); Byeong Geun KIM, Incheon (KR); Yoon Ki SA, Seoul (KR); Jung Suk GOH, Hwaseong-si (KR); Do Yeon KIM, Yongin-si (KR); Hyun YOON, Hwaseong-si (KR); Young Je UM, Busan (KR); Dong Ok AHN, Anyang-si (KR)

(73) Assignee: SEMES CO., LTD., Cheonan-si (KR)

(21) Appl. No.: 17/079,439

(22) Filed: Oct. 24, 2020

(30) Foreign Application Priority Data
Oct. 31, 2019 (KR) 10-2019-0137483

(51) Int. Cl. H01L 21/67; G03F 7/30; H01L 21/687

(52) U.S. Cl. CPC H01L 21/67069; G03F 7/3021; H01L 21/68764; H01L 21/67253; H01L 21/67103

(57) ABSTRACT

According to an exemplary embodiment of the present invention, a substrate treatment apparatus includes a chamber member including a treatment space in which a substrate is to be treated, a substrate support unit installed in the treatment space and supporting a substrate, a chemical ejection unit connected to the chamber member and ejecting a chemical fluid to the substrate support unit, and a steam supply unit connected to the chamber member and supplying steam to the chamber member.

### CROSS REFERENCE TO RELATED APPLICATION

The present application claims priority to Korean Patent Application No. 10-2019-0137483, filed Oct. 31, 2019, the entire contents of which are herein incorporated by reference.

### BACKGROUND OF THE INVENTION

### 1. Field of the Invention

The present invention relates to a substrate treatment apparatus and, more particularly, to a substrate treatment apparatus that is used to manufacture a semiconductor device.

### 2. Description of the Related Art

To manufacture a semiconductor device, a semiconductor substrate is subjected to various processes such as photolithography, etching, asking, ion implantation, thin film deposition, and cleaning to form a desired pattern on the semiconductor substrate.

In the case of a photolithography process, a photoresist film is first formed on a thin film formed on a substrate, and the photoresist film is exposed and developed to form a photoresist pattern. The photoresist pattern is used as an etching mask. By etching the thin film with the photoresist pattern provided on the thin film, an electrode film may be patterned to form electrodes.

As a method of etching the thin film, a dry etching technique or a wet etching technique is used. The wet etching technique may uniformly etch and is more productive than the dry etching technique, thereby being more popularly used than the dry etching technique.

Among various methods of wet etching, when etching silicon nitride thin films, a high-temperature single-type phosphoric acid etching process using a phosphoric acid etching solution is commonly used. The high-temperature single-type phosphoric acid etching process has an advantage of preventing degradation of etching attributable to re-adsorption of silica (SiO₂) compared to the other conventional wet etching methods. However, the high-temperature single-type phosphoric acid etching process has problems of causing a decrease in etching rate due to a sharp decrease in temperature of the wafer surface when a phosphoric acid etching solution is applied to the wafer surface and also causing decreases in etching rate and etching selectivity due to evaporation of water contained in a phosphoric acid etching solution.

### DOCUMENTS OF RELATED ART

Patent Document
(Patent Document 1) Korean Patent No. 10-0634122

### SUMMARY OF THE INVENTION

An objective of the present invention is to provide a substrate treatment apparatus capable of improving etching performance.

According to an exemplary embodiment of the present invention, a substrate treatment apparatus includes a chamber member including a treatment space in which a substrate is to be treated, a substrate support unit installed in the treatment space and configured to support a substrate, a chemical ejection unit connected to the chamber member and configured to eject a chemical fluid to the substrate support unit, and a steam supply unit connected to the chamber member and configured to supply steam to the chamber member.

The steam supply unit includes a steam generation member disposed outside the chamber member and configured to generate the steam, the steam being high pressurized steam at a high temperature, and a transfer member that connects the steam generation member and the chamber member to each other and is configured to transfer the steam to the chamber member.

The steam supply unit further includes a heating member installed on the transfer member and configured to heat the transfer member.

The apparatus further includes a discharge member connected to the chamber member and configured to discharge the steam to the outside from the chamber member.

The apparatus further includes a pressure measurement unit configured to measure an internal pressure of the chamber member.

The pressure measurement unit further includes a first pressure measurement member installed in a region via which the steam is supplied to the chamber member from the steam supply unit and configured to measure a first pressure of the steam supplied to the chamber member, and a second pressure measurement member installed in a region via which the steam is discharged to the outside from the discharge member and configured to measure a second pressure of the steam discharged from the discharge member.

The pressure measurement unit generates an internal pressure of the chamber member. The internal pressure of the chamber member corresponds to an average value of the first pressure measured by the first pressure measurement member and the second pressure measured by the second pressure measurement member.

The chamber member includes an upper chamber and a lower chamber that are separable from each other.

A pressure of the steam generated by the steam supply unit is within a range of 10 bars to 40 bars and a temperature of the steam is within a range of 180° C. to 250° C.

The apparatus further includes a fluid guide member connected to an upper surface of the treatment space of the chamber member and configured to prevent droplets resulting from the steam from falling onto the substrate.

The fluid guide member includes a first portion and a second portion. The first portion of the fluid guide member includes a first end connected to the upper surface of the chamber member and a second end connected to the second portion. The first portion of the fluid guide member is sloped down at a first angle from a vertical axis of the substrate support unit, the vertical axis being perpendicular to an upper surface of the substrate support unit. The first portion extends beyond a circumference of the substrate support unit.

The second portion is extended at a second angle from the vertical axis of the substrate support unit. The second portion of the fluid guide member is positioned outside the circumference of the substrate support unit.

The fluid guide member is made of a hydrophobic material.

The discharge member is configured to discharge the steam in a pulsed manner such that the internal pressure in the chamber member is maintained within a predetermined range on the basis of the internal pressure of the chamber member measured by the pressure measurement unit.

The apparatus further includes a heating member installed on the substrate support unit and configured to heat the substrate.

The heating member includes a heating coil or a light source.

According to an exemplary embodiment of the present invention, a substrate treatment apparatus for etching a silicon nitride thin film formed on a substrate includes a chamber member providing a high pressure treatment space, a spin chuck installed in the high pressure treatment space and configured to rotatably support a substrate, a chemical ejection unit connected to the chamber member and configured to eject a chemical fluid to the spin chuck, a steam supply unit connected to the chamber member and configured to supply steam to the chamber member, a discharge member connected to the chamber member and configured to discharge the steam to the outside from the chamber member, a pressure measurement unit configured to measure an internal pressure of the treatment space, and a controller configured to control operation of the discharge member.

The controller is configured to start, in response to the measured internal pressure exceeding a reference pressure, an operation of the discharge member.

The controller is configured to stop, in response to the measured internal pressure being equal to or lower than the reference pressure, the operation of the discharge member.

According to an exemplary embodiment of the present invention, a substrate treatment apparatus for treating a substrate with a chemical fluid includes a chamber member providing a treatment space and including an upper chamber and a lower chamber that are movable relative to each other in a direction of being moved away from or close to each other by a drive device, a spin chuck installed in the treatment space and configured to rotatably support a substrate; a chemical ejection unit connected to the chamber member and configured to pump a chemical fluid stored in a storage tank and to eject the chemical fluid onto the substrate supported on the spin chuck; a steam supply unit including a steam generation member disposed outside the chamber member and configured to generate hot high-pressurized steam, and a transfer member configured to connect the steam generation member and the chamber member to each other and to transfer steam generated by the steam generation member to the chamber member, a discharge member connected to the chamber member and configured to discharge the steam to the outside from the chamber member, and a fluid guide member provided in an upper portion of the treatment space and configured to be sloped down from a center portion of the treatment space to a periphery portion thereof.

### BRIEF DESCRIPTION OF THE DRAWINGS

The above and other objectives, features, and other advantages of the present invention will be more clearly understood from the following detailed description taken in conjunction with the accompanying drawings, in which:

FIG. 1 is a cross-view illustrating a substrate treatment apparatus according to a first embodiment of the present invention;

FIG. 2 is a view illustrating a state in which an upper chamber and a lower chamber are separated in the substrate treatment apparatus of FIG. 1;

FIG. 3 is a view illustrating a substrate treatment apparatus according to a second embodiment of the present invention;

FIG. 4 is a view illustrating a substrate treatment apparatus according to a third embodiment of the present invention; and

FIG. 5 is a view illustrating a substrate treatment apparatus according to a fourth embodiment of the present invention.

### DESCRIPTION OF THE EXEMPLARY EMBODIMENTS

Hereinbelow, exemplary embodiments of the present invention will be described in detail with reference to the accompanying drawings such that the invention may be easily practiced by those ordinarily skilled in the art to which the present invention pertains. The present invention may be embodied in various forms and should not be construed as being limited to the exemplary embodiments disclosed herein.

A description of elements that are not related to the invention will be omitted to clarify the invention, and identical or similar elements are denoted by identical or similar reference characters throughout the drawings and the detailed description below.

In various embodiments, components having the same configuration will be denoted by the same reference numerals, and only a representative embodiment will be described. For the other exemplary embodiments, only components that differ from those of the representative embodiment will not be described.

When an element is described as being “connected to”, “combined with”, or “coupled to” another element, it should be understood that the element may be connected to, combined with, or coupled to another element directly or with another element interposing therebetween. It will be further understood that the terms “comprises”, “comprising”, “includes”, and/or “including” when used herein, specify the presence of stated features, integers, steps, operations, elements, and/or components, but do not preclude the presence or addition of one or more other features, integers, steps, operations, elements, components, and/or groups thereof.

In addition, unless otherwise defined, all terms including technical and scientific terms used herein have the same meaning as commonly understood by those who are ordinarily skilled in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

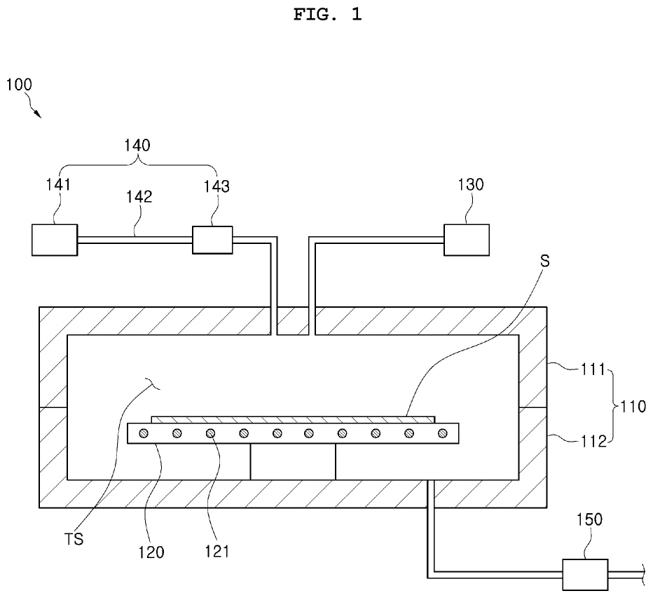

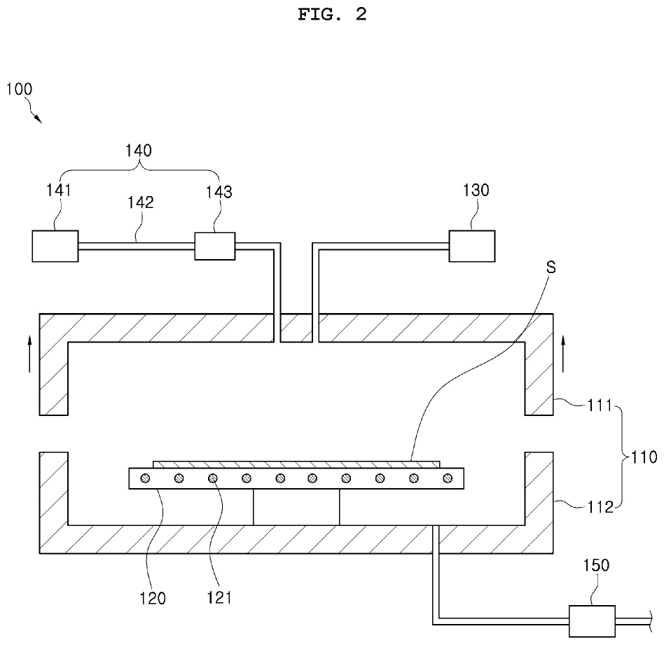

Referring to FIGS. 1 to 2, according to a first embodiment of the present invention, a substrate treatment apparatus 100 includes a chamber member 110, a substrate support unit 120, a chemical ejection unit 130, and a steam supply unit 140.

The chamber member 110 has a treatment space TS in which a substrate S is treated. The chamber member 110 has an inlet (not illustrated) at a first side thereof. The substrate S is supplied to the treatment space of the chamber member 110 through the inlet. Here, the substrate S is a wafer used to manufacture a semiconductor device. However, in the present invention, the substrate is not limited to the wafer.

The chamber member 110 included in the substrate treatment apparatus 100 according to the first embodiment of the present invention is be made of stainless steel (SUS) to stably maintain a certain internal pressure. The inner wall surface of the chamber member 110 is coated with a chemical-resistant resin such as polytetrafluoroethylene (PTFE) or polyimide (PI).

The chamber member 110 is composed of an upper chamber 111 and a lower chamber 112 that may be separated from each other (i.e., detachably attached to each other). The treatment space may be defined by an inner surface of the upper chamber 111 and an inner surface of the lower chamber 112. For example, an upper surface of the treatment space TS is defined by the inner surface of the upper chamber 111, and a lower surface of the treatment space TS is defined by the inner surface of the lower chamber 112. As to the chamber member 110, the upper chamber 111 and the lower chamber 112 are moved by a drive device (not illustrated) to be positioned a predetermined distance from each other or to be positioned close to each other.

The drive device may lift and lower either the upper chamber 111 or the lower chamber 112. When the upper chamber 111 and the lower chamber 112 are separated from each other, the interior of the chamber member 110 is exposed to the outside and the user may perform maintenance operations. The drive device may be a typical one that is usually used for conventional substrate treatment apparatuses. Therefore, a detailed description of the drive device will be omitted.

The substrate support unit 120 is installed in the treatment space. More specifically, the substrate support unit 120 is installed on the bottom surface in the treatment space of the chamber member 110. The substrate support unit 120 supports a substrate S.

For example, the substrate support unit 120 is equipped with a spin chuck. The spin chuck rotates the substrate S when the substrate S is seated on the substrate support unit 120. When a portion of the substrate support unit 120 is rotated, the substrate S is rotated together. When a chemical fluid is ejected to a center portion of the upper surface of the substrate S, the chemical fluid spreads to the edge of the substrate S due to centrifugal force. However, the construction of the substrate support unit 120 is not limited to a substrate support unit equipped with a spin chuck.

For example, the substrate support unit 120 includes a heating member 121. The heating member 121 is installed to be close to the substrate S. For example, the heating member 121 is implemented with a heating coil.

When the heating coil heats a portion of the substrate support unit 120, the substrate S is heated by the substrate support unit 120. The heating member 121 enables the substrate S to be maintained at a process temperature during the process. Alternatively, the heating member 121 may be implemented with a light source. An exemplary light source serving as the heating member is an infrared lamp. The infrared lamp heats the substrate by irradiating the substrate with infrared radiation. However, the heating member 121 is not limited to the heating coil or the light source and any device that may heat the substrate may be used as the heating member.

The chemical ejection unit 130 is connected to the chamber member 110 and ejects a chemical fluid to the substrate support unit 120. The chemical ejection unit 130 includes a nozzle (not illustrated) and a storage tank (not illustrated). A chemical fluid stored in the storage tank is pumped and ejected to the substrate S through the nozzle.

The chemical fluid may be used for a variety of purposes. The chemical fluid may be any one or more solutions selected from the group consisting of fluoric acid (HF), sulfuric acid (H₃SO₄), nitric acid (HNO₃), phosphoric acid (H₃PO₄), and SC-1 solution (which is a mixture of ammonium hydroxide (NH₄OH), hydrogen peroxide (H₂O₂), and water (H₂O)). As a gas used for drying, nitrogen (N₂), isopropyl alcohol (IPA), or the like may be used.

When the substrate treatment apparatus 100 according to the first embodiment of the present invention is an etching apparatus, the chemical fluid may be an etching solution. The etching solution may be, but is not limited to, an aqueous phosphate solution (H₃PO₄+H₂O). However, the etching solution is not limited thereto. The etching solution etches a thin film on the substrate S.

A chemical recovery unit (not illustrated) is installed around the substrate support unit 120. The chemical recovery unit is positioned near the substrate support unit 120 and collects a chemical fluid scattering from the substrate support unit 120. In more detail, the chemical recovery unit is installed to surround the entire circumference of the substrate support unit 120 and recovers a chemical fluid scattering from the substrate support unit 120.

The chemical recovery unit may separately recover different chemicals used in a process. In a process of treating the substrate S, each of the various chemicals may be separately introduced into and stored in the chemical recovery unit.

For example, the collected chemicals are transferred to external chemical regeneration units (not illustrated) via recovery lines so that the chemicals may be regenerated and reused. The chemical regeneration unit is an apparatus for regenerating a chemical so as to be reused by controlling the concentration and temperature of the used chemical used and by filtering the used chemical.

Contaminants are generated from the particles generated during the process of treating the substrate S. The contaminants may be accumulated in the chemical recovery unit. In addition, contaminants such as fumes may be generated from the remaining chemicals. These contaminants are removed by the chemical regeneration unit. In the subsequent process, the chemical regeneration unit prevents the substrate S from being polluted by the contaminated chemical.

The chemical ejection unit 130 and the substrate support unit 120 are ones that are usually included in conventional substrate treatment apparatuses. Therefore, a detailed description of the chemical ejection unit 130 and the substrate support unit 120 will not be redundantly given here.

The steam supply unit 140 is connected to the chamber member 110 and supplies steam to the chamber member 110. The steam supply unit 140 includes, for example, a steam generation member 141 and a transfer member 142.

The steam generation member 141 is positioned outside the chamber member 110 and generates steam having a high temperature and a high pressure. The steam generation member 141 generates steam by heating deionized water (DIW).

The transfer member 142 connects the steam generation member 141 and the chamber member 110. The transfer member 142 transfers steam to the chamber member 110. Although the illustration shows that the transfer member 142 is connected to an upper end of the chamber member 110, the present invention is not limited thereto. Alternatively, the transfer member 142 may be connected to a side surface or a lower end of the chamber member 110.

The steam supply unit 140 optionally includes a heating member 143. The heating member 143 is installed on the transfer member 142.

The heating member 143 heats the transfer member 142. Therefore, it is possible to prevent the temperature of deionized water transferred along the transfer member 142 from decreasing.

The pressure of the steam generated by the steam supply unit 140 may be within a range of 10 to 40 bars and the temperature of the steam may be within a range of 180° C. to 250° C.

When the pressure of the steam is 10 bars, the temperature of the steam is approximately 180° C. When the pressure of the steam is 20 bars, the temperature of the steam is approximately 210° C. In addition, when the pressure of the steam is 40 bars, the temperature of the steam is approximately 250° C. The steam contains the maximum amount of moisture in the temperature and pressure conditions described above. Therefore, under such conditions, the steam containing the maximum amount of moisture comes in direct contact with the substrate S. In addition, since the treatment space is in a state of high pressure and high temperature, the chemical fluid may contain a large amount of water as a solvent.

The steam supply unit 140 supplies steam to the treatment space of the chamber member 110 before the chemical fluid is ejected to the substrate S. Alternatively, the steam supply unit 140 may supply steam to the treatment space of the chamber member 110 after the chemical fluid is ejected to the substrate S.

In the process of etching the substrate S, the hot steam supplied by the steam supply unit 140 significantly increases the humidity in the treatment space. The high pressure steam increases the internal pressure of the treatment space of the chamber member 110.

Generally, the saturated vapor temperature of water proportionally increases with the internal pressure. Therefore, as the internal pressure of the treatment space is increased, the saturated vapor temperature of water increases. Accordingly, it is possible to prevent the water contained in an etchant from evaporating at the target temperature. Here, the target temperature is a reaction temperature at which etching may be actively performed.

Since it is possible to prevent the water contained in the etchant on the substrate from evaporating, the etching rate of a thin film of silicon nitride (Si₃N₄) may be improved. That is, the substrate treatment apparatus 100 according to the present invention uses hot high-pressure steam to prevent deterioration of etching rate and etching selectivity.

The substrate treatment apparatus 100 according to the first embodiment of the present invention optionally further includes a discharge member 150.

The discharge member 150 is connected to the chamber member 110. The discharge member 150 discharges steam to the outside from the chamber member 110. The discharge member 150 is coupled to a lower portion of the chamber member 110.

When high-pressure gas is continuously fed into the chamber member 110 that is sealed, the internal pressure of the chamber member 110 is increased. Therefore, in order to maintain the internal pressure of the chamber member 110 at a constant level, the gas in the chamber member 110 needs to be discharged.

The discharge member 150 discharges steam to the outside from the chamber member 110. Therefore, the discharge member 150 prevents the internal pressure of the chamber member 110 from excessively rising. The discharge member 150 may also discharges water resulting from the steam.

The discharge member 150 discharges steam in a pulsed manner, i.e., intermittently. In more detail, the discharge member 150 discharges a predetermined amount of steam and then takes a break for a predetermined time. The discharge member 150 performs the cycle a target number of times.

The pulsed steam discharging is more advantageous in maintaining the pressure of the treatment space of the chamber member 110 within a predetermined range than the continuous steam discharging. When the steam is continuously discharged, there is a possibility that the pressure of the treatment space of the chamber member 110 sharply decreases.

The discharge member 150 operates in a pulsed manner such that the pressure of the treatment chamber is maintained within a predetermined range based on the measurement results of the pressure measurement unit 260. The discharge member 150 operates on the basis of the measurement results of the pressure measurement unit 260, and this operation of the discharge member 150 will be described in detail below.

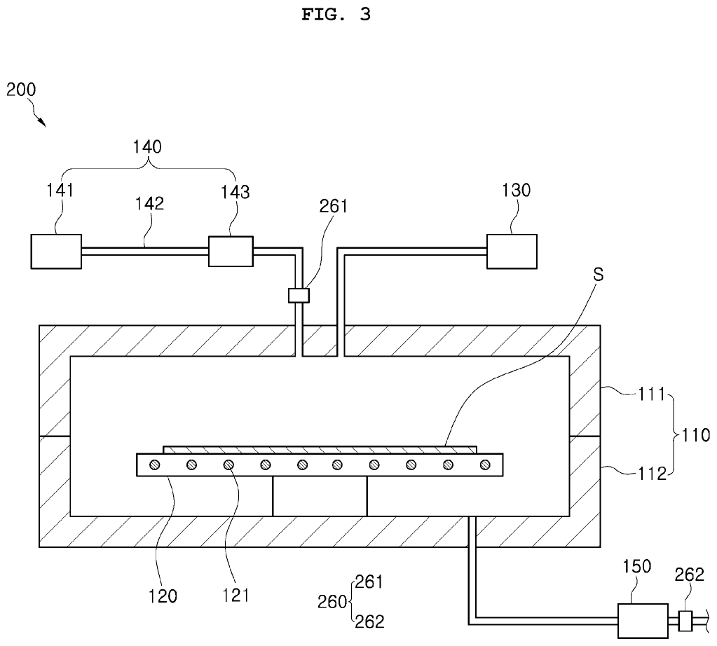

Referring to FIG. 3, a substrate treatment apparatus 200 according to a second embodiment of the present invention additionally includes a pressure measurement unit 260.

The pressure measurement unit 260 measures the pressure of the treatment space of the chamber member 110.

The pressure measurement unit 260 includes, for example, a first pressure measurement member 261 and a second pressure measurement member 262.

The first pressure measurement member 261 is installed in a region through which steam is supplied to the chamber member 110 from the steam supply unit 140. For example, the first pressure measurement member 261 may be installed on a transfer member 142.

In an example embodiment, the first pressure measurement member 261 may be installed on a portion of the transfer member 142, the portion being close to the chamber member 110. The first pressure measurement member 261 measures the pressure of the steam. The first pressure measurement member 261 is, for example, a pressure sensor.

The second pressure measurement member 262 is installed in a region via which the steam is discharged to the outside from the discharge member 150. The second pressure measurement member 262 measures the pressure of the steam. The second pressure measurement member 262 is, for example, a pressure sensor.

The pressure measurement unit treats the average value of the pressure measured by the first pressure measurement member and the pressure measured by the second pressure measurement member as the internal pressure of the chamber member 110.

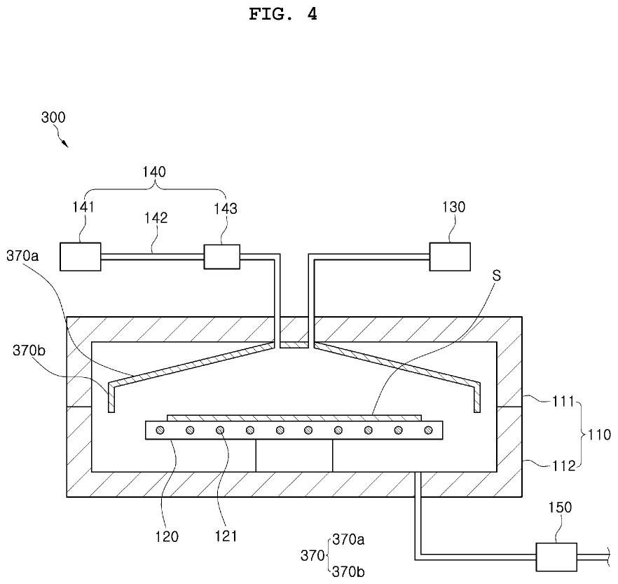

Referring to FIG. 4, a substrate treatment apparatus 300 according to a third embodiment of the present invention additionally includes a fluid guide member 370.

The fluid guide member 370 prevents droplets that are the condensate of the steam from falling onto the substrate S. The fluid guide member 370 is connected to an upper portion (i.e., an upper surface) of the treatment space of the chamber member 110.

When the steam supplied to the chamber member 110 comes into contact with the inside wall surface of the chamber member 110, the steam turns into droplets. When the droplets are formed on the side surface or the bottom surface of the chamber member 110, the droplets flow downward. The fluid guide member 370 is sloped down from a center portion of the chamber member 110 (i.e., the treatment space) to a periphery portion thereof.

The droplets formed on the fluid guide member 370 flow along the surface of the fluid guide member 370 to the lower edge 370b and are collected at the bottom surface of the chamber member 110.

The fluid guide member 370 includes a first portion 370a and a second portion 370b. The first portion 370a of the fluid guide member 370 includes a first end connected to the upper surface of the chamber member 110 and a second end connected to the second portion 370b of the fluid guide member 370. The first portion 370a of the fluid guide member 370 is sloped down at a first angle from a vertical axis of the substrate support unit 120. The vertical axis is perpendicular to an upper surface of the substrate support unit 120. The first portion 370a extends beyond the circumference of the substrate support unit 120. The second portion 370b of the fluid guide member 370 is extended at a second angle from the vertical axis of the substrate support unit 120. In an example embodiment, the second angle is greater than the first angle, and may have zero degree. For example, the second portion 370b extends in parallel to the vertical axis of the substrate support unit 120. The second portion 370b of the fluid guide member 370 is positioned outside the circumference of the substrate support unit 120.

The lower edge (i.e., the second portion) 370b of the fluid guide member 370 is positioned closer to the wall surface of the chamber member 110 in terms of a lateral direction than the substrate support unit 120. The fluid guide member 370 is larger than the upper surface of the substrate support unit 120. Therefore, the lower edge 370b of the fluid guide member 370 is positioned not to overlap the substrate support unit 120 when viewed from above.

The fluid guide member 370 is made of a hydrophobic material. Accordingly, droplets famed on the surface of the fluid guide member 370 may not fall to the substrate S. The droplets flow down to the lower end of the fluid guide member 370 and fall onto the bottom surface of the chamber member 110. Therefore, the substrate treatment apparatus 300 according to the third embodiment of the present invention may prevent the substrate S from being contaminated with the droplets.

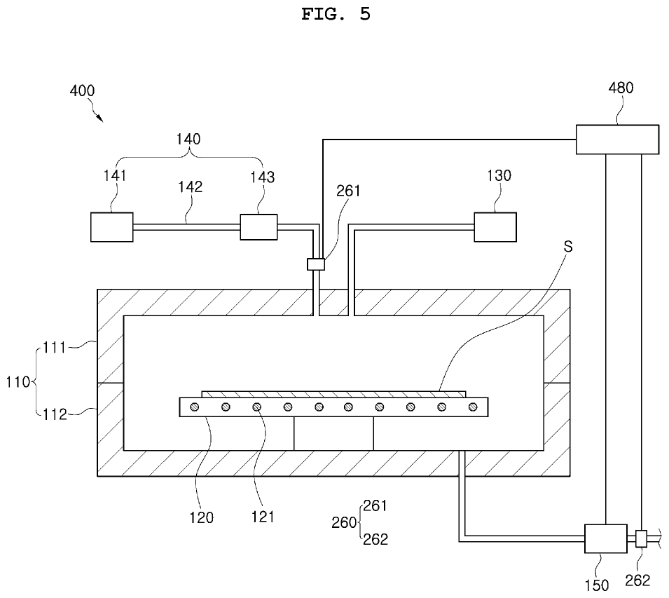

Referring to FIG. 5, a substrate treatment apparatus 400 according to a fourth embodiment of the present invention includes a chamber member 110, a spin chuck (not illustrated), a chemical ejection unit 130, a steam supply unit 140, a discharge member 150, a pressure measurement unit 260, and a controller 480.

The chamber member 110, the chemical ejection unit 130, the steam supply unit 140, the discharge member 150, and the pressure measurement unit 260 are the same as those included in the substrate treatment apparatus 200 that has been described with reference to FIG. 3. Therefore, a redundant description of those elements will be omitted here. The spin chuck corresponds to the substrate support unit 120 included in the substrate treatment apparatus 200 according to the embodiment described above. Therefore, a redundant description of the spin chuck will also be omitted.

The controller 480 controls the operation of the discharge member 150 on the basis of the measurement results of the pressure measurement unit 260. In more detail, the controller 480 operates the discharge member 150 when it is determined that the pressure in the treatment chamber exceeds a reference pressure.

As described above, an appropriate pressure of the treatment space is within a range of 10 to 40 bars. The controller 480 operates the discharge member 150 to discharge steam when the pressure in the treatment space gradually increases and reaches about 40 bars. As the steam is discharged from the treatment space, the pressure of the treatment space is gradually lowered.

On the contrary, the controller 480 stops the operation of the discharge member 150 when it is determined that the pressure in the treatment space is equal to or lower than the reference pressure. For example, the controller 480 stops the operation of the discharge member 150 when the pressure in the treatment chamber gradually decreases from over 10 bars and reaches almost 10 bars.

As described above, the substrate treatment apparatus 400 according to the fourth embodiment includes the controller 480, and the controller 480 controls the operation of the discharge member 150 on the basis of the measurement results of the pressure measurement unit 260. Therefore, the pressure of the treatment space is always maintained at an optimum pressure for etching the thin film.

Referring to FIG. 1, the substrate treatment apparatus 100 according to the present invention includes the steam supply unit 140 that supplies hot high-pressure steam to the chamber member 110. The hot steam supplied by the steam supply unit increases the humidity in the treatment space. The high pressure steam increases the internal pressure of the treatment space of the chamber member 110.

Since the internal pressure of the treatment space increases, the saturated vapor temperature of water also increases. Accordingly, it is possible to prevent the water contained in an etchant (i.e. etching solution) from evaporating at the target temperature. Since it is possible to prevent the water contained in the etchant on the substrate from evaporating, the etching rate of a thin film formed of silicon nitride (Si₃N₄) may be improved. That is, the substrate treatment apparatus 100 according to the present invention uses hot high-pressure steam to prevent deterioration of etching rate and etching selectivity.

Although various embodiments of the present invention have been described above, the drawings and detailed description of the present invention are intended to illustrate the present invention and are not intended to limit the scope of the present invention. Therefore, those skilled in the art will appreciate that various modifications and equivalents thereto are possible. Accordingly, the true technical protection scope of the present invention should be determined by the technical idea defined in the appended claims.

What is claimed is:

1. A substrate treatment apparatus comprising:
a chamber member including a treatment space in which a substrate is to be treated;
a substrate support unit installed in the treatment space and configured to support a substrate;
a chemical ejection unit connected to the chamber member and configured to eject a chemical fluid to the substrate support unit; and
a steam supply unit connected to the chamber member and configured to supply steam to the chamber member.

2. The apparatus according to claim 1,
wherein the steam supply unit comprises:
a steam generation member disposed outside the chamber member and configured to generate the steam, the steam being high pressurized steam at a high temperature; and
a transfer member that connects the steam generation member and the chamber member to each other and is configured to transfer the steam to the chamber member.

3. The apparatus according to claim 2,
wherein the steam supply unit further comprises a heating member installed on the transfer member and configured to heat the transfer member.

4. The apparatus according to claim 1, further comprising:
a discharge member connected to the chamber member and configured to discharge the steam to the outside from the chamber member.

5. The apparatus according to claim 4, further comprising:
a pressure measurement unit configured to measure an internal pressure of the chamber member.

6. The apparatus according to claim 5,
wherein the pressure measurement unit further comprises:
a first pressure measurement member installed in a region via which the steam is supplied to the chamber member from the steam supply unit and configured to measure a first pressure of the steam supplied to the chamber member; and
a second pressure measurement member installed in a region via which the steam is discharged to the outside from the discharge member and configured to measure a second pressure of the steam discharged from the discharge member.

7. The apparatus according to claim 6,
wherein the pressure measurement unit is configured to generate an internal pressure of the chamber member, and
wherein the internal pressure of the chamber member corresponds to an average value of the first pressure measured by the first pressure measurement member and the second pressure measured by the second pressure measurement member.

8. The apparatus according to claim 1,
wherein the chamber member comprises an upper chamber and a lower chamber that are configured to be separable from each other.

9. The apparatus according to claim 1,
wherein a pressure of the steam generated by the steam supply unit is within a range of 10 bars to 40 bars and a temperature of the steam is within a range of 180° C. to 250° C.

10. The apparatus according to claim 1, further comprising:
a fluid guide member connected to an upper surface of the treatment space of the chamber member and configured to prevent droplets resulting from the steam from falling onto the substrate.

11. The apparatus according to claim 10,
wherein the fluid guide member includes a first portion and a second portion,
wherein the first portion of the fluid guide member includes a first end connected to the upper surface of the chamber member and a second end connected to the second portion,
wherein the first portion of the fluid guide member is sloped down at a first angle from a vertical axis of the substrate support unit, the vertical axis being perpendicular to an upper surface of the substrate support unit, and
wherein the first portion extends beyond a circumference of the substrate support unit.

12. The apparatus according to claim 11,
wherein the second portion is extended at a second angle from the vertical axis of the substrate support unit, and
wherein the second portion of the fluid guide member is positioned outside the circumference of the substrate support unit.

13. The apparatus according to claim 10,
wherein the fluid guide member is made of a hydrophobic material.

14. The apparatus according to claim 5,
wherein the discharge member is configured to discharge the steam in a pulsed manner such that the internal pressure in the chamber member is maintained within a predetermined range on the basis of the internal pressure of the chamber member measured by the pressure measurement unit.

15. The apparatus according to claim 1, further comprising:
a heating member installed on the substrate support unit and configured to heat the substrate.

16. The apparatus according to claim 15,
wherein the heating member includes a heating coil or a light source.

17. A substrate treatment apparatus for etching a silicon nitride thin film formed on a substrate, the apparatus comprising:
a chamber member providing a high pressure treatment space;
a spin chuck installed in the high pressure treatment space and configured to rotatably support a substrate;
a chemical ejection unit connected to the chamber member and configured to eject a chemical fluid to the spin chuck;
a steam supply unit connected to the chamber member and configured to supply steam to the chamber member;
a discharge member connected to the chamber member and configured to discharge the steam to the outside from the chamber member;
a pressure measurement unit configured to measure an internal pressure of the treatment space; and
a controller configured to control operation of the discharge member.

18. The apparatus according to claim 17,
wherein the controller is configured to start, in response to the measured internal pressure exceeding a reference pressure, an operation of the discharge member.

19. The apparatus according to claim 18,
wherein the controller is configured to stop, in response to the measured internal pressure being equal to or lower than the reference pressure, the operation of the discharge member.

20. A substrate treatment apparatus for treating a substrate with a chemical fluid, the apparatus comprising:
a chamber member providing a treatment space and including an upper chamber and a lower chamber that are movable relative to each other in a direction of being moved away from or close to each other by a drive device;
a spin chuck installed in the treatment space and configured to rotatably support a substrate;
a chemical ejection unit connected to the chamber member and configured to pump a chemical fluid stored in a storage tank and to eject the chemical fluid onto the substrate supported on the spin chuck;
a steam supply unit including a steam generation member disposed outside the chamber member and configured to generate hot high-pressurized steam, and a transfer member configured to connect the steam generation member and the chamber member to each other and to transfer steam generated by the steam generation member to the chamber member;
a discharge member connected to the chamber member and configured to discharge the steam to the outside from the chamber member; and
a fluid guide member provided in an upper portion of the treatment space and configured to be sloped down from a center portion of the treatment space to a periphery portion thereof.
